(19) United States
(12) Patent Application Publication
(10) Pub. No.: US 2005/0110550 A1
(43) Pub. Date: May 26, 2005

(54) DC offset cancellation in a direct-conversion receiver

(76) Inventors: Qian Shi, San Diego, CA (US); Liang Dai, Carlsbad, CA (US); Kevin Hsi-Huai Wang, San Diego, CA (US)

Correspondence Address: HungChang Lin, 8 Schindler Ct., Silver Spring, MD, 20903, US

(21) Appl. No.: 10/719,833

(22) Filed: Nov. 24, 2003

(51) Int. Cl. H03L 5/00

(52) U.S. Cl. 327/307

(57) ABSTRACT

The DCOC block is used in ZIF BB to form HPF function to cancel dc offset with a penalty of small silicon area and low power consumption. It is a LPF plus a voltage to current conversion (VIC) resistor, and can hook up with any BB opamp used in signal path, to form a feedback loop, with or without signal gain stages in the loop. The BB opamp is used as a summing point. The summing method is input current summing. The cutoff frequency of the HPF function is thus defined by the integrator, the VIC resistor, and the feedback resistor in the summing opamp. The presence of the VIC resistor can drastically reduce the integrator capacitor and resistor values and thus save silicon area or improve receiver performance.

### BACKGROUND OF THE INVENTION

1. Field of the Invention

The present invention relates in general to direct-conversion receivers, or zero intermediate frequency (ZIF) receivers, in particular to circuit for canceling dc offset in such receivers.

2. Brief Description of Related Art

From the handbook “The ARRL Handbook For Radio Amateurs”, Published by the American Radio Relay League, sixty-eight edition, 1991, the direct-conversion receiver (zero IF) was made known and has received a great deal of interest over the past few years by significantly improving on-chip integration. In a direct-conversion receiver, dc offset from RF front end and baseband (BB) can be amplified by many gain stages and thus may saturate the receiver at certain node depending on the amplitude of dc offset and the gain in the case. Even if the dc offset does not saturate the receiver, it can still cause malfunction when the dc offset is very close to the signal level. Therefore effective canceling the dc offset in the receiver is necessary. In U.S. Pat. No. 6,509,777, a programmable gain amplifier in series with a transconductance (gm) amplifier is placed in the feedback path, as shown in FIG. 1, to form a highpass filtering (HPF) function with variable cutoff frequencies. In U.S. Pat. No. 6,442,380, a passive HPF combined by a capacitor and a variable resistor to form variable cutoff frequencies is placed in several places in signal path in a ZIF receiver, as shown in FIG. 2.

### SUMMARY OF THE INVENTION

An object of this invention is to optimize the trade off between the silicon area and power consumption for dc offset cancellation (DCOC) in a ZIF receiver. This invention can save large ratio of silicon area by reducing the integrator capacitor value used in conjunction with an integrator opamp by a factor of 3 to 4. The power consumed by the integrator opamp in today's deep submicron (DSM) and very deep submicron (VDSM) technologies can be very minor. Thus the use of the integrator does not increase much power in comparison with the use of a passive high-pass filter (HPF) for DC offset cancellation in U.S. Pat. No. 6,442,380. This invention uses active opamp integrator plus input current summing feedback which allows more leeway in choosing smaller integrating capacitor value and less power consumption comparing to U.S. Pat. No. 6,509,777 which used transconductor and output current summing feedback topology. This invention uses a continuous time active integrator to realize low-pass filter (LPF), while in U.S. Pat. No. 6,509,777, the DC offset reduction circuit used switched-capacitor RC LPF which needs a clock signal to control the switch and increases the circuit complexity. The clock generator was not shown there but was necessarily used. This invention has the feature that the integrator opamp is easily realized to have very high DC gain and very large output swing, moderate bandwidth and small power consumption in modern DSM/VDSM technologies, and thus can provide a very large DC attenuation to achieve superior DC offset reduction. The resulted DC offset is very small compared to the signal and thus can be considered as being canceled.

In this invention, a feedback loop type HPF function is implemented with an active opamp integrator and voltage-to-current conversion (VIC) resistor driven by the integrator. The cutoff frequency is made variable by varying the input resistor in the integrator and the output VIC resistor. Any opamp used in the signal path in the receiver can be used as a summing point for the DCOC input and output signal.

The opamp can be designed for low power and providing rail to rail output voltage swing. This large output swing makes the design robust against larger DC offset to accumulate in a ZIF receiver [to accumulate] before it is cancelled by the DCOC block. This means designer can use fewer DCOC blocks in the receiver. This will reduce the silicon area and save power too.

### BRIEF DESCRIPTION OF THE DRAWINGS

FIG. 1 shows a block diagram of a ZIF receiver analog front end commonly used nowadays in wireless communication systems. The base-band (BB) analog to digital converter (ADC) and digital signal processing (DSP) block are not shown. RF signal is received by the antenna and filtered by a RF bandpass (BPF) filter. Then the signal is amplified by the low noise amplifier (LNA) and directly down-converts from RF to BB by mixing with the local oscillator (LO) signal in the mixer. The signal is then filtered again by a lowpass filter (LPF). The amplitude of the signal is controlled by digital automatic gain control (AGC) system and amplified by a variable gain amplifier (VGA). The signal is passed to BB DSP portion by BB driver. A DCOC scheme can be used in this ZIF receiver at any point in signal path from BB LPF to BB driver, provided that at that point there is an opamp in signal path which will be used as summing point.

FIG. 2 shows a DCOC circuit in U.S. Pat. No. 6,509,777.

FIG. 3 shows a DCOC circuit in U.S. Pat. No. 6,442,380.

FIG. 4 shows a DCOC circuit in present invention.

FIG. 5 shows how the present invention circuit is used in a ZIF receiver.

FIG. 6 shows the simulation result of the DCOC effect.

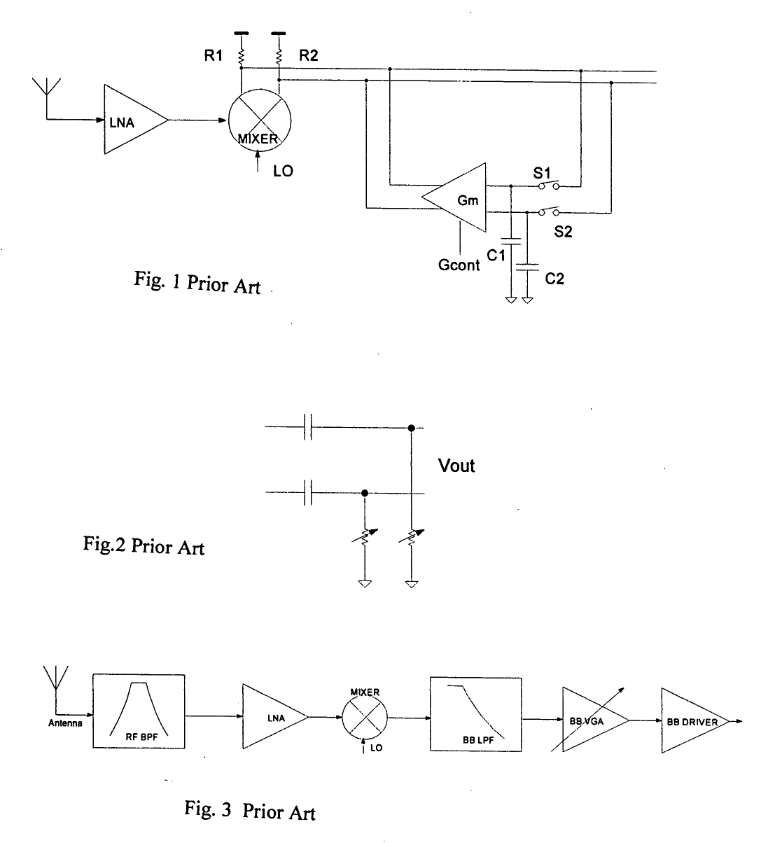

### DETAILED DESCRIPTION OF THE INVENTION

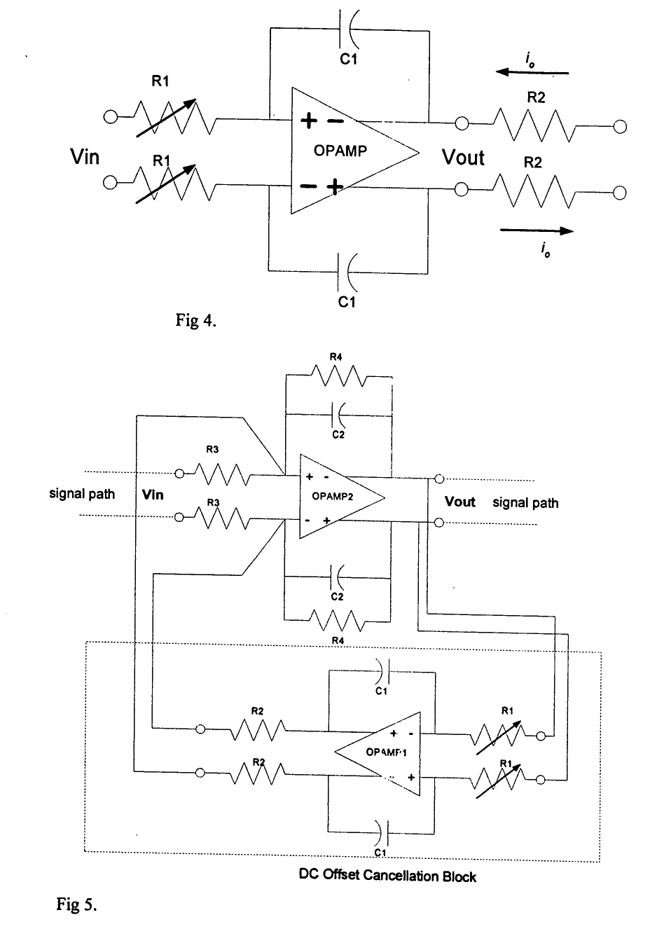

FIG. 4 shows the DC offset cancellation block (DCOC) of the present invention The circuit is used to feed back the integrated component from the output of a base-band amplifier of a ZIP receiver to a preceding stage. By negative feedback of the integrated component, the DC offset is minimized. The DCOC block comprises an OPAMP connected as an integrator or active low pass filter. The integrator has a feedback capacitor C1 connected between the inverting input and the non-inverting output, and another capacitor C1 connected between the non-inverting input and the inverting output. Each input is connected to a differential input voltage V in through a resistor R1. R1 is variable to change the cutoff frequency of the low pass filter. The output voltage V out of the integrator is connected to a virtual ground through a resistor R2 to flow an output current io equal to V out/R2. Thus V out is converted into iₒₙ, and R2 constitutes a voltage-to-current converter VIC.

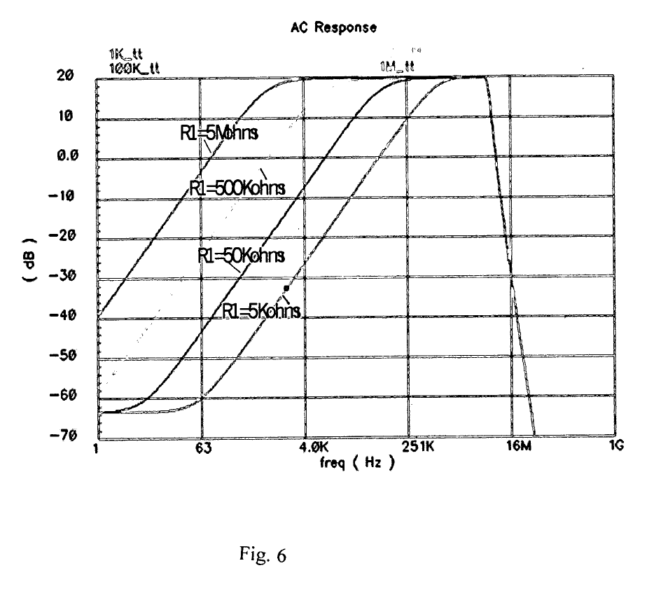

The DCOC is connected as a feedback block to a current summing stage of the base-band amplifier as shown in FIG. 5. The stage includes an opamp OPAMP2 connected as an active low pass filter. A parallel R4 and C2 is connected between the inverting input and the non-inverting output, and another parallel R4 and C2 is connected between the non-inverting input and the inverting output. Each input is fed with a signal V in through resistor R3 as input signal current, which is summed with the feedback current from the DCOC block. The output voltage V out of OPAMP2 is then proportional to the sum of the signal voltage and the feedback voltage from the DCOC block.

The DCOC circuit can be applied to both the in phase component I path and the quadrature component Q path of a ZIF receiver. The integrated voltage is transferred into current by VIC resistor and fed back to the input of the opamp OPAMP2 in signal path. The cutoff frequency is therefore determined by four factors: integrator resistor R1, capacitor C2, opamp OPAMP1, and VIC resistor R2, and OPAMP2 feedback resistor R₄. A small increase in R₁/R₄ ratio can result a large reduction of the integrator capacitor value. In a ZIF receiver, the HPF cutoff frequency in signal path must maintain at a very low level so that the signal bandwidth degradation can be kept in minimum. To have this feature, the integrator capacitor and resistor need to have very large value to provide a large time constant. For example, a 1MΩresistor and 150 pF capacitor form the time constant which results a cutoff frequency around 1KHz. The presence of VIC resistor can contribute to the time constant linearly. As shown in FIG. 5, if R₄=5KΩ, R₂=20KΩ, to achieve 1 KHz cutoff frequency, then C₁=37.5 pF. The silicon area for R₄ and R₂ can be easily less than 100 um², but for C₁=150 pF, it can be as large as 135,000 um², because C₁ is a floating metal-metal capacitor. It is obvious that the use of VIC R₂ saves about 75% silicon area. Because R₂ contrubutes to the time constant, the mentioned feature to save silicon area applies to reduce integrating resistor value, R₁ in FIG. 5, in another case where a small C₁ and a large R₁ are chosen for 1 KHz cutoff frequency, for example, from original R₁=10MΩ, C₁=15 pF, shrinking to R₁=2.5MΩ, C₁=15 pF. The silicon area is also saved about 75%. If R₁=10MΩ is kept, the cutoff frequency is now set to 250 Hz. The receiver performance improves because less signal bandwidth is sacrificed. In a word, the invention can either cut the chip cost by saving silicon area, or improve the chip performance. It is a flexibility for right decision to make by a chip designer. The DCOC circuit itself used in the present invention has a lowpass filtering function. From FIG. 4, the transfer function can be simplified as:

$$H ( s ) = \frac{{v}_{o}}{{v}_{i n}} = - \frac{A ( s )}{1 + s ( 1 + A ( s ) ) {R}_{1} {C}_{1}}$$

where νₒ is the output voltage, νᵢₙ is the input voltage, R₁ is the integrating resistance, C₁ is the integrating capacitance, and the opamp OPAMP1 is assumed to have a gain of A(s) . When OPAMP1 becomes ideal, the transfer function becomes ideal integrator function:

$${H}_{ideal} ( s ) = \frac{{v}_{o}}{{v}_{i n}} = - \frac{1}{{sR}_{1} {C}_{1}}$$

The integrated output voltage νₒᵤₜ is then converted to current by the VIC resistor, R₂ in FIG. 4, when the other side of R₂ away from the opamp is connected to an virtual ground point. A virtual ground point is the input of an opamp where there is no AC voltage swing.

When the DCOC block is used as negative feedback with the signal path as shown in FIG. 5, the high frequency (HF) components are filtered out by the LPF. Only dc and low frequency (LF) components remain after the LPF and are fed back to the signal path, in inverse polarity. The result is that the HF components are kept in the signal path, while the dc and LF components are removed or largely attenuated from the signal spectrum, right after the summing point. The overall operation is thus a HPF function for the signal. For an ideal opamp in the integrator, the cutoff frequency is proportional to R₄/(2πR₁C₁R₂).

The summing method chosen in present invention is input current summing. It is realized by summing the signal current and DCOC current at the input of an opamp in the signal path. The opamp can be in a filter internal stage, or in variable gain amplifier (VGA), or in BB driver. FIG. 5 gives such an example. The operation can be interpreted as follows: If there is a DC offset inherent in the output voltage V out of OPAMP2, it integrates through the integrator OPAMP1 and convert to current through VIC resistor R₂. This current then sums with the signal input current in reverse polarity. Thus at the output, the DC offset will reduce. The feedback loop bandwidth can be adjusted by the variable resistor R₁ in the integrator. This variable bandwidth can be used to adjust the cutoff frequency. The attenuation level at DC and LF is controlled by the bandwidth of the loop and the DC gain of the opamp in the integrator. The opamp in the integrator OPAMP1 must have large output swing, to maintain good linearity and effectively cancel DC offset. Besides, a larger swing can generate larger current through VIC resistor R₂. In another word, one can tolerate smaller integrating capacitor C₁ for fixed DC offset, or the same C₁ for larger DC offset, to save silicon area in design. In this invention, a rail-to-rail (full supply voltage) output opamp is used. Multiple DCOC circuits can be placed in the ZIF receiver, to form multiple DCOC blocks. Each block can involve or do not involve gain in signal path, depending on the particular system specification.

The input current summing method has a superior feature over the output current summing method as described in U.S. Pat. No. 6,509,777, or passive HPF AC coupler as described in U.S. Pat. No. 6,442,380, because it can save power or greatly reduce capacitor or resistor value in the integrator to achieve the same HPF transfer function. For comparison, assume ideal opamp in integrator and fixed integrating resistor value R₁. In an output current summing method as shown in FIG. 2, the integrating voltage is added to a device input such as the gate of MOSFET or the base of BJT. The transconductance (gm) of the device then transfer the voltage into a current and summing it with the signal current which is amplified by the transconductance gm of another similar device in signal path at the output of the device. Generally, it needs more current to cancel the DC offset at output of the device than at the input of the device because the DC offset in signal at output of the device is amplified as well as the signal by the other device. Therefore, the gm of the DCOC device cannot be too small. Thus this method consumes more power than the input current summing method. In a passive BPF method on the other hand, the HPF cut off frequency is defined as f_{c}=1/(2πRC). For the same f_{c}, the input current summing method has an integrating RC time constant that is proportional to R₂/R₄ as shown in FIG. 5. This can drastically reduce the integrating R or C value and thus the silicon area, by easily choosing R₂>>R₄ in design. A simulation result is provided in FIG. 6. The simulation is based on a ZIF receiver BB 5^{th}-order LPF with the DCOC block added to the output and input of the last opamp in the filter. The total gain of the LPF is set to 20 dB. Four cutoff frequencies from 1 KHz to 1 MHz are achieved by adjusting variable resistor R₁. The parameters in this simulation are: R₁=5MΩ,500KΩ,50KΩ,5KΩ,C₁=7.5 pF, R₂=20KΩR₄=5KΩ. It is flexible to add the DCOC block in some other way, like adding it to the output of the last opamp and input of an internal opamp that is before the last opamp. To involve how many stages in signal path to the loop is an option of the designer according to his particular design.

While differential stages are used in the preferred embodiment of the BB amplifier as described in FIG. 5, it will be obvious to those skilled in the art that the same technique can be used for single-ended stages. For instance, the opamp can have one non-inverting input grounded to effect a virtual ground at the inverting input, where the signal current and the feedback current are summed. Single-ended opamps can be used in the BB low pass stage, the BB VGA or the BB driver. Other modifications of the embodiment can be made without departing from the spirit of the present invention. Such modifications are all within the scope of the present invention.

1. A DC offset cancellation system for a direct -conversion receiver, comprising:
a base-band (BB) amplifier including at least one current summing stage, to which a BB signal is fed as first input current; and
a DC offset cancellation (DCOC) block serving as a negative feedback circuit fed from the output of said BB amplifier a second input current to said current summing stage, comprising:
an integrator, and
a voltage to current converter (VIC) to feed a negative feedback current to the second input current of said current summing stage.

2. The DC offset cancellation system as described in claim 1, wherein said current summing stage has differential inputs, said integrator has a differential outputs, and said VIC has differential outputs.

3. The DC offset cancellation system as described in claim 2, wherein said current summing stage is an operational amplifier.

4. The DC offset cancellation system as described in claim 2, wherein said current summing stage operates as an active low pass filter.

5. The DC offset cancellation system as described in claim 2,
wherein said integrator comprises two input resistors and two negative feedback capacitors between the differential inputs and the differential outputs of a second operational amplifier.

6. The DC cancellation system as described in claim 5, wherein said VIC are two resistors each connected between the outputs of said second operational amplifier and said differential inputs of said current summing stage.

7. The DC offset cancellation system as described in claim 6, wherein the two resistors are variable.

8. The DC offset cancellation system as described in claim 1,
wherein said current summing stage is an operational amplifier with one input grounded,
wherein said integrator has singled-ended output, and
wherein said VIC is a resistor connected between said single-ended output and said second input to said summing stage to convert the voltage output of said integrator to a current input to said second input which is at virtual ground.

9. The DC offset cancellation system as described in claim 1, where the summing stage is selected from a base-band low-pass filter stage, base-band variable gain amplifier and band-band driver stage.

10. The DC offset cancellation system as described in claim 1, further comprising more than one DCOC block feeding more than one stage of said BB amplifier.
